(19) United States
(12) Patent Application Publication
(10) Pub. No.: US 2008/0214139 A1
(43) Pub. Date: Sep. 4, 2008

(54) Multistage Resonant Amplifier System and Method

(76) Inventors: Matteo Conta, Irvine, CA (US); Valentina Della Torre, Irvine, CA (US); Francesco Svelto, Pavia (IT); Giuseppe Cusmai, Pavia (IT)

Correspondence Address: JOHN BRUCKNER, P.C., P.O. BOX 490, FLAGSTAFF, AZ, 86002, US

(21) Appl. No.: 11/795,745

(22) PCT Filed: Sep. 26, 2006
(86) PCT No.: PCT/GB2006/003589

§ 371 Date: Jul. 20, 2007

Related U.S. Application Data
(60) Provisional application No. 60/720,254, filed on Sep. 26, 2005.

(51) Int. Cl. H04B 1/16; H03G 3/10

(52) U.S. Cl. 455/341; 330/284

(57) ABSTRACT

A radio-frequency receiver for, e.g., receiving GPS signals in a cellular telephone has an input, a first gain stage in the form of a linear low noise amplifier with voltage-voltage feedback and a resonant load, and a second gain stage based on a common source input transconductor. Associated with the input and the first gain stage is a filter comprising a notch filter part for rejecting an interfering signal, e.g. a cell phone transmitter signal, and, connected between the parallel resonant circuit and the input, a series capacitance which, in combination with the inductor of the parallel-resonant circuit, forms a series-resonant circuit to provide a low impedance path at a wanted signal frequency.

The present invention relates generally to electronic communications, and more particularly to a system and method for amplifying a very low level radio frequency signal before it is further processed in a communications system or device.

A very steep growth in location-related services is foreseen in the next few years by industry analysts. Cellular phones with embedded Global Positioning Systems (GPS) engines will enable network-based positioning methods. Assisted GPS solutions allow a direct migration path into 3G handsets besides being more accurate than cell-tower-based ones. Co-existence of a GPS receiver together with cell-phones on the same Printed Circuit Board (PCB) poses new challenges, though. Power savings and a high integration level, in order to simplify the application board, are key targets. In this way, battery life is extended and bill of materials reduced. On the other hand, the limited isolation between transceivers makes leaking signals dangerous interferers.

Well-known GPS implementations include a passive filter to reduce the in-band noise of the signal. In these implementations the passive filter has very stringent requirements, adding substantial cost and real estate to the GPS functionality.

In light of the above, there exists a need for a new low-noise amplifier (LNA) architecture that reduces the need for passive filters in a GPS implementation.

The receiver front-end amplifier disclosed hereinafter addresses a need for eliminating an external passive filter in a low-power LNA for GPS applications. The LNA has a notch filter, followed by a first stage gain that is a highly linear voltage-voltage feedback LC-loaded low noise amplifier and a second stage gain.

The invention provides a receiver as set out in the claims appended hereto.

The invention will now be described by way of example with reference to the drawings in which:

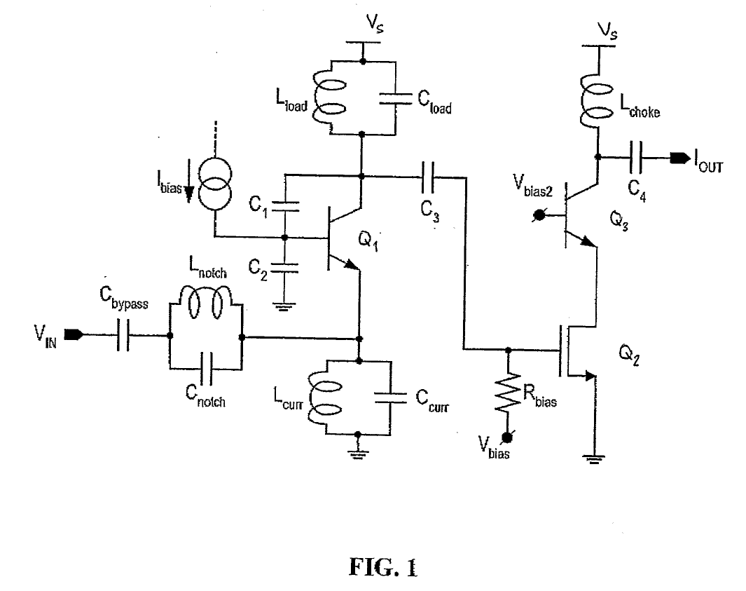

FIG. 1 is a circuit diagram of an exemplary low noise amplifier.

In accordance with the present invention, a low noise amplifier for a GPS receiver within a cellular phone is composed of a notch filter, followed by a first gain stage that is an highly linear voltage-voltage feedback LC-loaded low noise amplifier and a second gain stage.

Referring to FIG. 1, the amplifier has an input terminal V_{IN} from which a received signal is fed via a series-connected capacitor C_{bypass} to a notch filter comprising the parallel-resonant combination of an inductor L_{notch} and a capacitor C_{notch}. This resonant combination is coupled in series between the input V_{IN} and the emitter terminal of an amplifier element Q₁ in the form of a bipolar transistor connected as a common-base amplifier. The emitter terminal is also connected to ground via a second parallel-tuned resonant circuit L_{curr}, C_{curr}, included for frequency response shaping. The notch filter is tuned to a frequency or frequency band associated with known interference which, in the case of a cellular phone, comprises one or more signals associated with the cellular phone functions, such as the transmitter output signal.

Q₁ and its associated components act as a low noise amplifier (LNA). Coupled between its collector terminal and the supply rail V_{S} is an output resonant circuit L_{load}, C_{load} tuned to the wanted signal frequency. Voltage-voltage feedback is provided by a capacitive voltage divider C₁, C₂, C₁ being coupled between the collector terminal and the base terminal of transistor Q₁, and C₂ being connected between the base terminal and ground. Transistor Q₁ is provided with a bias current by a current source I_{bias} coupled to its base terminal.

The LNA with voltage-voltage feedback and an inductor-capacitor load is chosen due to its superior linearity performance, at given power consumption, over the inductively degenerated topology.

The notch filter is provided at a blocking frequency and is resonated out the wanted signal frequency by means of the capacitor C_{bypass}. The input impedance is thus the load impedance reflected by the feedback loop. Capacitor C_{bypass} forms a series-resonant circuit with an inductor L_{notch}, resonant at the wanted signal frequency to allow a low impedance path from the input V_{IN} to Q₁ at that frequency.

In this way, attenuation of the wanted (GPS) signal by the notch is largely avoided despite the wanted signal frequency being adjacent the interference frequency.

Coupled to the output of the first gain stage formed by Q₁ and its associated components via coupling capacitor C₃ is a second gain stage having a common source input transconductor Q₂ and an output device Q₃. Field-effect transistor Q₂ has its gate terminal connected to coupling capacitor C₃ to receive the amplified and filtered version of the received signal. Transistor Q₂ is biased from a first bias voltage source V_{bias} via a resistor R_{bias} coupled to the gate terminal. The source of transistor Q₂ is connected to ground, whilst its drain terminal is coupled to the emitter of an output bipolar transistor Q₃, the collector of which is coupled to the supply rail VS via a choke L_{choke}. Bias for the output transistor Q₃ is provided from a second bias source V_{bias2} connected directly to the base terminal of transistor Q₃. Transistor Q₃ acts as a buffer and the amplified output signal obtained from the collector of the transistor Q₃ is delivered to an output terminal I_{OUT} via an output coupling capacitor C₄.

1. A radio frequency receiver for receiving a wanted signal at a wanted signal frequency, the receiver including a front end amplifier which comprises an input, an input gain stage and, associated with the input and the input gain stage, a filter in the form of a first resonant circuit producing a notch in the amplifier frequency response at a blocking frequency, wherein the filter further comprises a reactance which forms, in conjunction with a component of the first resonant circuit, a second resonant circuit increasing gain at the wanted signal frequency.

2. A receiver according to claim 1, wherein the first resonant circuit comprises a parallel-resonant inductor and capacitor combination coupled in series between the input and the input gain stage, and the reactance comprises a second capacitor which is coupled in series with the first resonant circuit, the second capacitor and the inductor together forming a series-resonant combination resonant at the wanted signal frequency.

3. A receiver according to claim 1 or claim 2, wherein the reactance is on the input side of the first resonant circuit.

4. A receiver according to any preceding claim, wherein the first gain stage comprises the combination of an amplifier element, a voltage feedback loop and a resonant load.

5. A receiver according to claim 4, further comprising a second gain stage including a common source transconductor.

6. A radio-frequency receiver including a front-end amplifier comprising:
a signal blocking notch filter;
a first gain stage comprising the combination of an amplifier element, a voltage feedback loop and a resonant load; and
a second gain stage coupled to the first gain stage and including a common source transconductor.

7. A radio-frequency receiver having a front-end amplifier which comprises: an input notch filter; a bipolar transistor first gain stage incorporating voltage feedback and a load element comprising an inductance and a capacitance in a resonant combination; and a second gain stage incorporating a field-effect transistor coupled to receive a signal from the first gain stage.

8. A receiver for receiving signals from a satellite-based global positioning system, comprising: a front-end amplifier having a notch filter arranged to block an interfering signal; a substantially linear tuned first gain stage that is associated with the notch filter and has a feedback loop; and a second gain stage coupled to an output of the first gain stage, the second gain stage comprising a common source transconductor element.

9. A system comprising:
an architecture for a Low Noise Amplifier that is part of a radio frequency front end; and
a notch filter that provides the blocker rejection and is resonated out at signal frequency by means of a capacitor; and
a first gain stage of the front end composed by a highly linear voltage-voltage feedback LC (Inductor, Capacitor) loaded low noise amplifier; and
a second gain stage of the front end that is based on a common source input transconductor.

10. A receiver according to any preceding claim, wherein the notch filter comprises a parallel-tuned circuit coupled in an input path of the first gain stage.

11. A receiver according to any preceding claim, wherein the first gain stage comprises a common-base bipolar transistor amplifier having a parallel-tuned circuit connected between an emitter connection of the transistor and ground.

12. A receiver according to any preceding claim, wherein the load of the first gain stage comprises a parallel-tuned circuit resonant at the frequency of the wanted signal.

13. A receiver according to any preceding claim, wherein the feedback loop comprises a capacitive voltage divider coupled between an output of the first gain stage and a radio frequency ground, the divider tap being connected to an input terminal of the first gain stage.

14. A receiver according to any of claims 6 to 9, wherein the first gain stage comprises a bipolar transistor connected in common base configuration and having a bias current source connected to the base, a parallel-tuned circuit coupled between the collector and a radio frequency ground, and a feedback loop between the collector and the base, the feedback loop comprising a capacitive voltage divider between the collector and a radio frequency ground with the divider tap connected to the base.

15. A receiver according to any preceding claim, wherein the second gain stage comprises a field-effect transistor connected as a common source amplifier element acting as an input device, and having, coupled to the field-effect transistor drain, a bipolar transistor acting as an output buffer, the emitter of the output device being coupled to the field-effect transistor drain and the collector forming an output of the front-end amplifier.

16. A radio frequency amplifier for a satellite signal receiver comprising a notch filter, a substantially linear first gain stage with voltage-voltage feedback and an LC-loaded output, and a second gain stage.

17. A method of amplifying a wanted radio-frequency signal in the presence of an interfering signal, comprising:
feeding a received signal to a first gain stage via a notch filter,
amplifying the signal in the first gain stage using an amplifier element having a voltage-voltage feedback loop and a resonant load,
feeding an amplified signal from the first gain stage to a second gain stage using a common source input transconductor.
